(19) United States
(12) Patent Application Publication
(10) Pub. No.: US 2011/0039397 A1
(43) Pub. Date: Feb. 17, 2011

(54) Structures and methods to separate microchips from a wafer

(76) Inventors: Huilong Zhu, Poughkeepsie, NY (US); Zhijiong Luo, Poughkeepsie, NY (US)

Correspondence Address: Huilong Zhu, 93 Autumn Dr., Poughkeepsie, Dutchess, NY, 12603, US

(21) Appl. No.: 12/806,619

(22) Filed: Aug. 17, 2010

Related U.S. Application Data
(60) Provisional application No. 61/274,382, filed on Aug. 17, 2009.

(51) Int. Cl. H01L 21/78

(52) U.S. Cl. 438/462; 257/E21.599

(57) ABSTRACT

Structures and methods for separating chips or ICs from a wafer are disclosed. To save area and manufacturing costs, deep trench formation combining with mechanical bending or lateral etch is used to separate chips or ICs from a wafer.

This non-provisional application claims the benefit of the provisional application filed with the United States Patent and Trademark Office as Ser. No. 61/274,382 entitled “STRUCTURES AND METHODS TO SEPARATE MICROCHIPS FROM A WAFER” filed on Aug. 17, 2009.

### BACKGROUND OF THE INVENTION

The present invention relates generally to a method, for dicing a wafer, in which a wafer having a plurality of electronic circuits formed at one side thereof is diced, to thereby separate it into the plurality of semiconductor chips.

Since the development of integrated circuit technology, computers and computer storage devices have been make from wafers of semiconductor material comprising a plurality of integrated circuits. After a wafer is made, the circuits are typically separated from each other by dicing the wafer into individual chips. To reduce area penalty and manufacturing costs, it is necessary to reduce the area consumed by dicing process, especially when the individual chip is small such as RFID tags.

In the ordinary arts, the individual IC chips are separated from the semiconductor substrate by using dicing saw or laser beam, which unavoidable can cause cracks, breaks of the edge, or melting of the edge. And due to the relative large size of dicing saw and laser beam, both consume quite large areas when cutting IC chips from the substrate. For this reason, various ideas were proposed to address this issue. For example, as described in U.S. Pat. No. 7,211,370, photolithography and dry etching is used to cutting IC chips from the substrate. However, technically it is quite difficult to cut through the whole thickness of the substrate, and due to the depth of the etching, it is unavoidable to have a relative large lateral dimension as well, and it can add to the unwanted waste area from the substrate.

Compared to the prior arts, our invention can reduce the area penalty and manufacturing cost during dicing process, and our invention can reduce the damages in the process. Furthermore, our invention can produce IC chips with thin thickness, which is very desirable in the following packaging.

### BRIEF SUMMARY OF THE INVENTION

Structures and methods for separating chips or ICs from a wafer are disclosed. Deep trench formation combining with mechanical bending or lateral etch is used to separate chips or ICs from a wafer, which can dramatically reduce area penalty caused by conventional saw dicing and then reduce costs of chip or IC manufacturing.

This invention provides methods and structures to dicing integrated circuit chips from the semiconductor wafers. The methods and structures disclosed in this invention avoid the cracks, breaks of the edge, melting of the edge and other damages. This invention reduced the area penalty in the dicing process as well. It increases both the IC chips production yields and quality. Furthermore, this invention provides a process to produce IC chips with thin thickness, which is very desirable in many applications.

A first aspect of the invention provides a process for separating the integrated circuit chips from a semiconductor wafer, the said process comprising the steps of forming the parallel, substantially first vertical trenches in the semiconductor wafer from the front side of the silicon wafers by using photolithography and RIE process; forming the wider second vertical trenches from the backside of the semiconductor; bending the semiconductor wafer to separate the integrated circuit chips, during the bending process, the semiconductor wafer may attached to a layer of rubber or any other soft materials. Also, alternatively, after forming the first vertical trenches from the front side of the silicon wafers, the whole wafer can be thinned down from the backside, then bending the semiconductor wafer to separate the integrated circuit chips.

A second aspect of the invention provides a process for separating the integrated circuit chips from a semiconductor wafer, the said process comprising the steps of forming parallel, substantially vertical trenches in the processed semiconductor wafers by using photolithography and RIE process; forming etching-resistant spacers on the sidewalls of the said vertical trenches; forming the extensions of the said vertical trenches; etching lateral channels from the extensions of the said vertical trenches, preferably by using the wet etching process; the lateral channels substantially connects the adjacent vertical trenches, separating the integrated circuit chips from the semiconductor substrate.

### BRIEF DESCRIPTION OF THE DRAWINGS

The features of the invention are believed to be novel and the element characteristics of the invention are set forth with particularity in the appended claims.

The figures are for illustration purposes only and are not drawn to scale. The invention itself, however, both as to organization and method of operation, will best be understood by reference to the following detailed description taken in conjunction with the accompanying drawings in which:

In one embodiment, FIGS. 1.1 to 1.6 are cross sectional views which illustrate the various process steps in separating a wafer, in which the wafer having a plurality of electronic circuits formed at one side thereof, into the plurality of semiconductor chips.

In another embodiment, FIGS. 2.1 to 2.6 are cross sectional views which illustrate the various process steps in separating the wafer into the plurality of semiconductor chips.

FIGS. 1.6 and 2.6 are cross sectional views illustrating the final structure achieved according to the present invention.

### DETAILED DESCRIPTION OF THE INVENTION

Structures and methods for separating chips or ICs from a wafer are disclosed. To save area and manufacturing Costs, deep trench formation combining with mechanical bending or lateral etch is used to separate chips or ICs from a wafer.

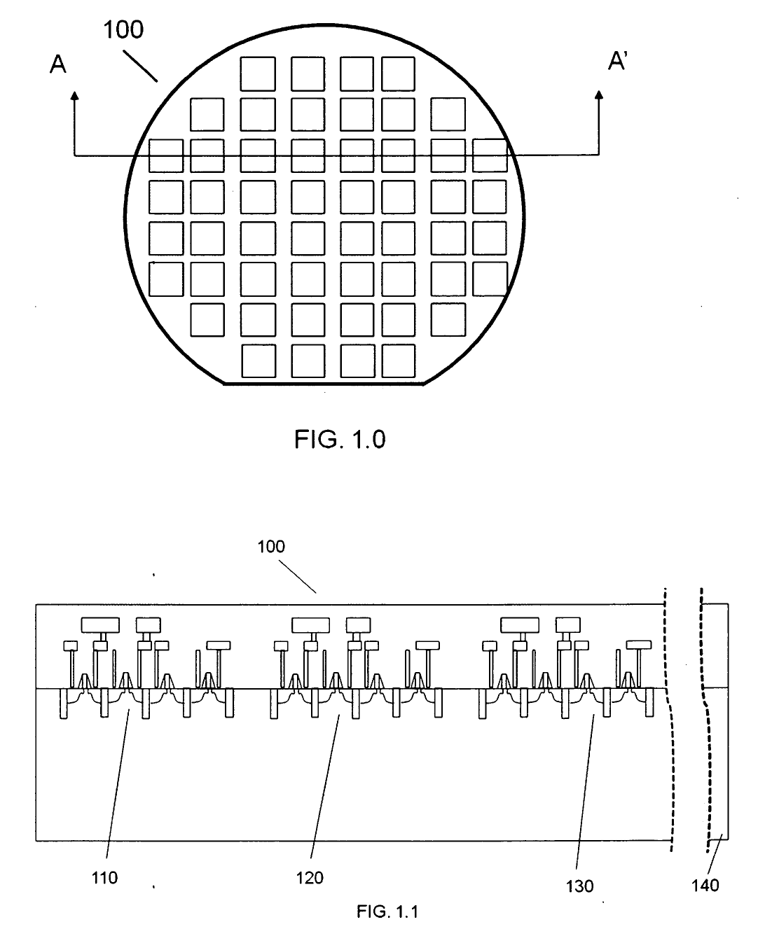

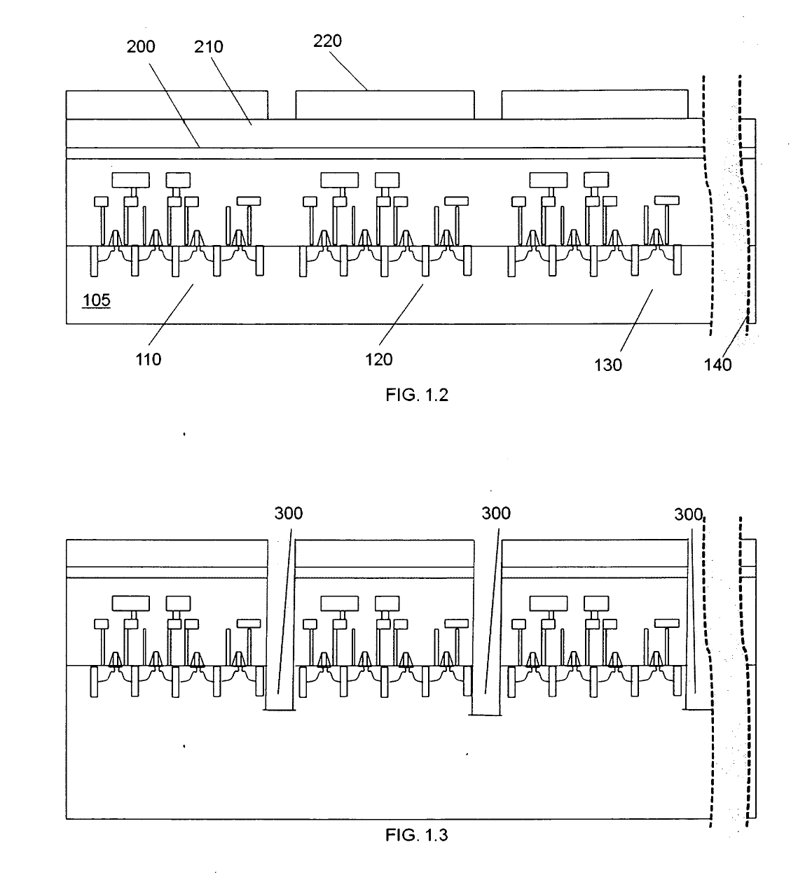

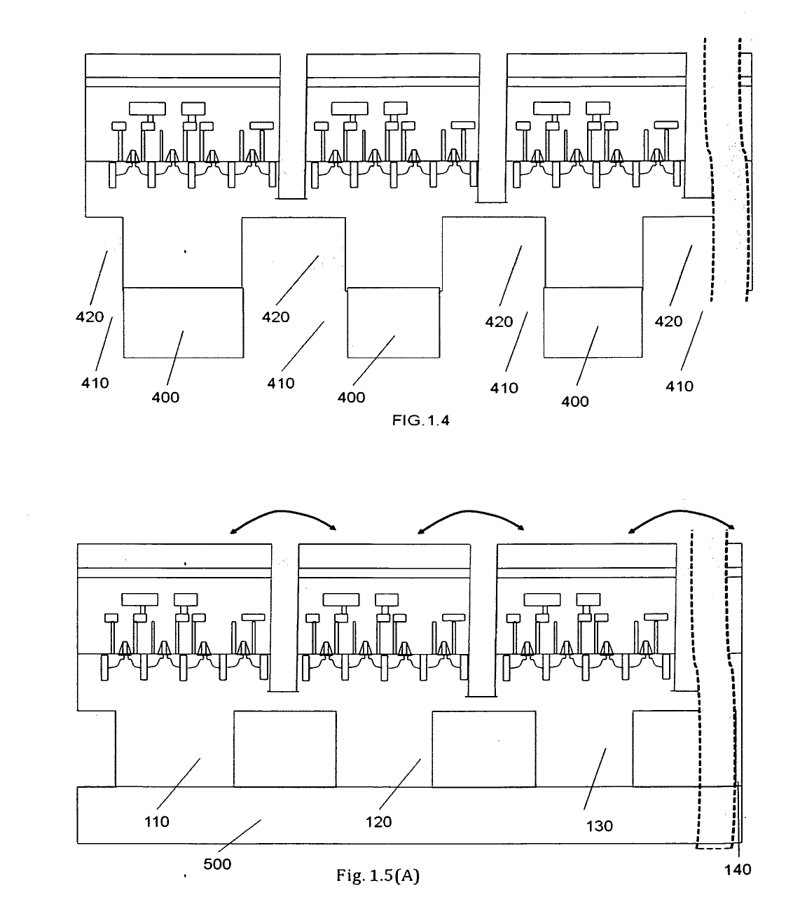

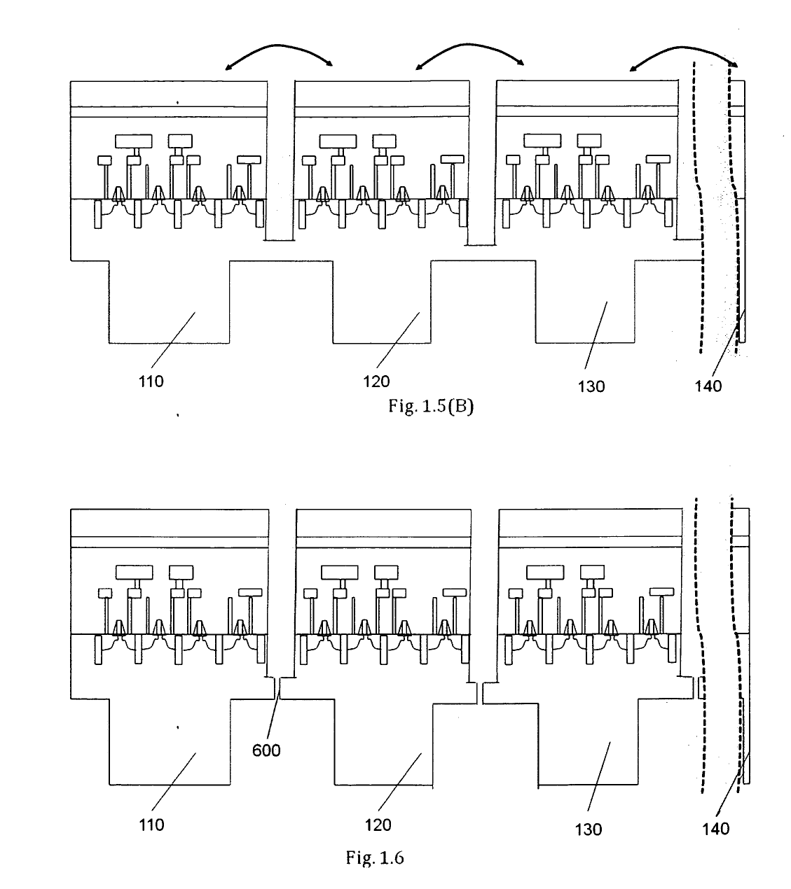

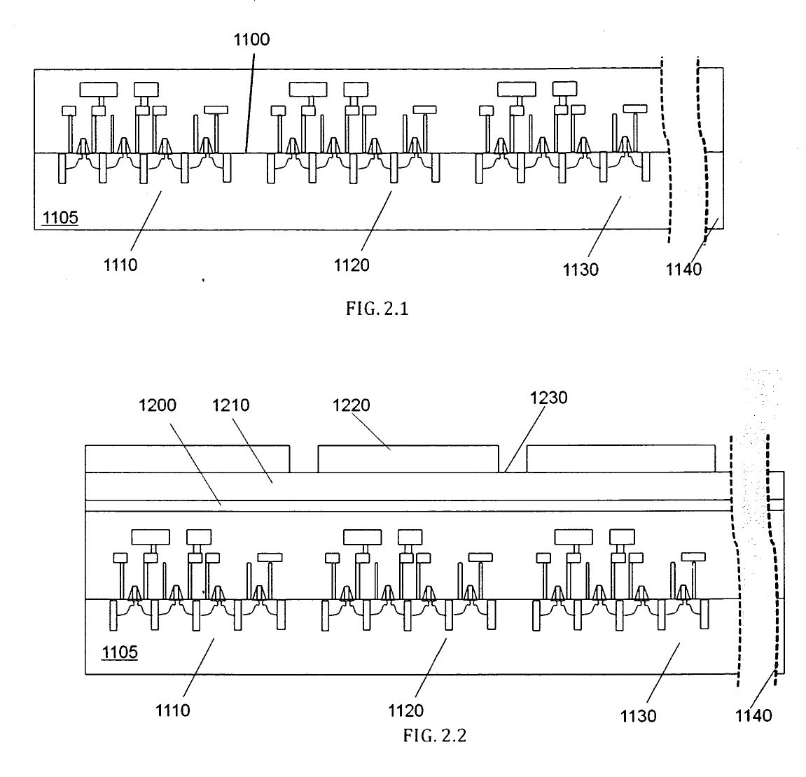

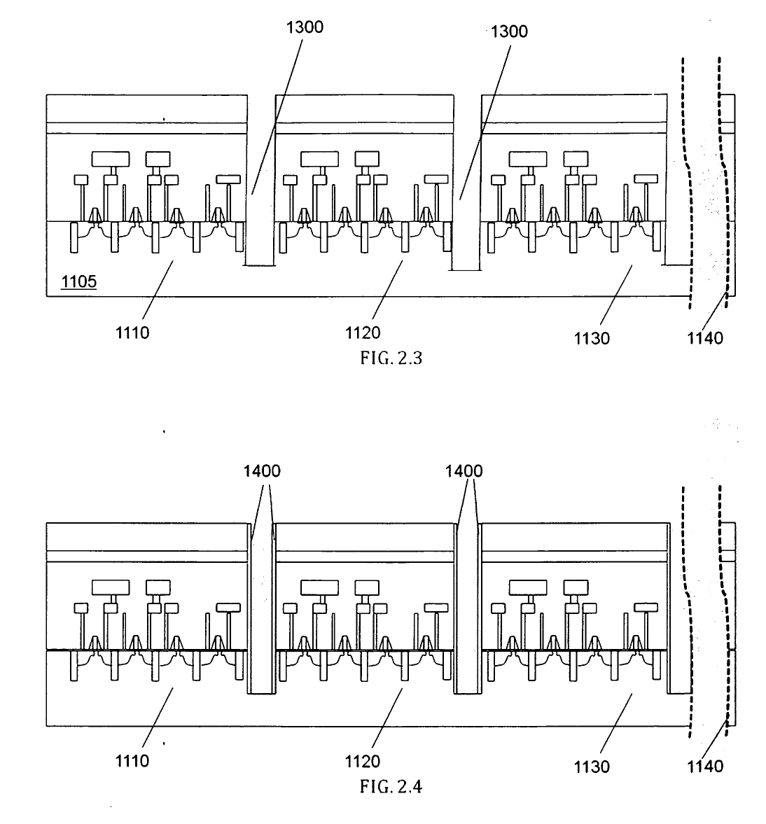

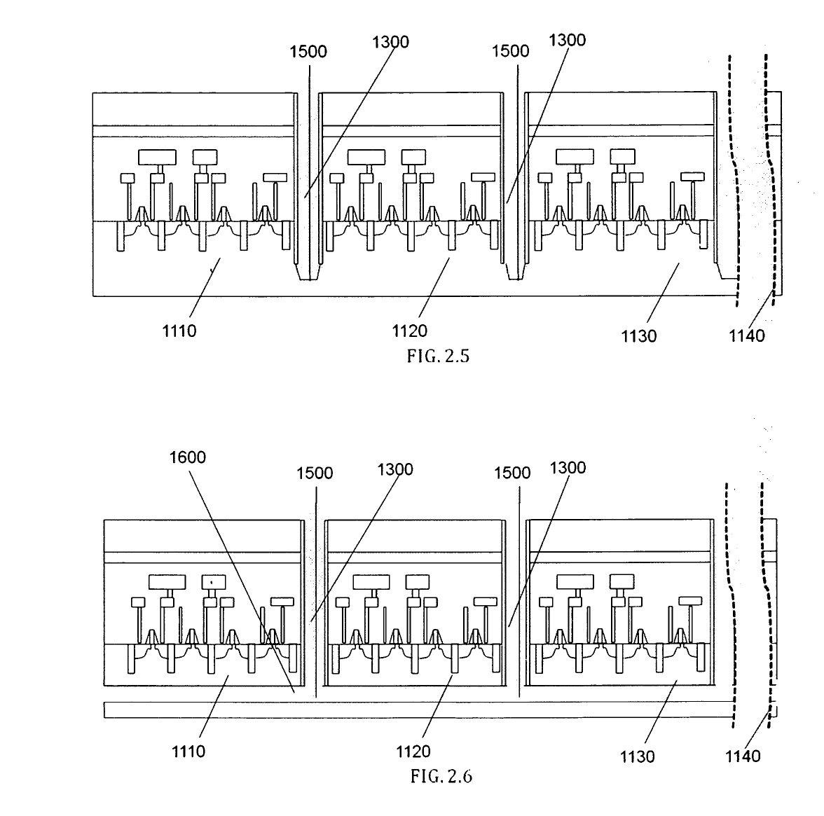

Referring now to the drawings in more detail, FIG. 1.0 showing the top view of a semiconductor structure 100, FIG. 1.1 showing the cross sectional view of a semiconductor structure 100 cutting through A-A′. FIG. 1.1 there is illustrated the semiconductor structure 100 having semiconductor substrate 105, having a first IC 110, having a second IC 120, having a third IC 130, and having a n^{th} IC 140. The semiconductor substrate 105 useful for the present invention is any semiconductor material including but not limited to group IV semiconductors such as silicon, silicon germanium, or germanium, a III-V compound semiconductor, or a II-VI compound semiconductor and combination thereof. The ICs of 110, 120, 130 and 140 are any integrated circuits including but not limited to RFID tags, computer chips and computer storage chips.

Referring now to FIG. 1.2, an oxide film 200 (preferably 10-100 nm thick) and a nitride film 210 (preferably 50-500 nm thick) are deposited on the top surface of the ICs of 110, 120, 130, and 140. A patterned photo-resist 220 with openings 230 (preferably about 10-50 um in size) for trench RIE is formed. The oxide film 200 and the nitride 210 are deposited by any method including but not limited to CVD, PECVD, and ALD. The patterned photo-resist 220 is formed by a conventional lithographic method. The oxide film 200 is any oxide materials including but not limited to SiO2, Fluorine Doped Silicon Dioxide, Carbon Doped Silicon Dioxide, Porous Silicon Dioxide, Porous Carbon doped Silicon Dioxide, Spin-on organic polymeric dielectrics, Porous SiLKSpin-on silicone based polymeric dielectric, and combination thereof.

Referring now to cross-section FIG. 1.3, the pattern openings 230 in the patterned photo-resist 220 have been etched into the nitride film 210, the oxide film 200, the areas among the ICs of 110, 120, 130, and 140, and the semiconductor substrate 105 by a conventional reactive ion etching (RIE) process to form trench 300 in the semiconductor structure 105. The depth of the trench 300 is about 20-600 um. Another embodiment is to form trench 300 before the formation of ICs of 110, 120, 130, and 140.

Referring now to FIG. 1.4, a patterned photo-resist 400 with openings 410 (preferably about 20-500 um in size) on the back side the semiconductor structure 100 is formed. The openings 410 are approximately aligned with the trenches 300. The pattern openings 410 in the patterned photo-resist 400 have been etched into the semiconductor substrate 105 by a conventional reactive ion etching (RIE) process to form trench 420 in the semiconductor structure 105. The trench 420 does not extend into the trench 300. The depth of the trench 420 is about 200-600 um.

Referring now to FIG. 1.5(A), the patterned photo-resist 400 is removed. The semiconductor substrate 105 is glued on a rubber 500 and then the ICs 110, 120, 130, and 140 are bended down to separate them each other.

Referring now to FIG. 1.5(B), in another embodiment, the patterned photo-resist 400 is removed. The ICs 110, 120, 130, and 140 are directly bended down to separate them each other.

FIG. 1.6 is a cross sectional views illustrating the final structure achieved according to the present invention. Boundary 600 is formed after the separating.

Also, alternatively, after forming the first vertical trenches from the front side of the silicon wafers, the whole wafer can be thinned down from the backside, then bending the semiconductor wafer to separate the integrated circuit chips.

Referring now to the drawings in more detail, FIG. 2.1 showing the cross sectional view of a semiconductor structure 1100. FIG. 2.1 there is illustrated the semiconductor structure 1100 having semiconductor substrate 1105, having a first IC 1110, having a second IC 1120, having a third IC 1130, and having an n^{th} IC 1140. The semiconductor substrate 1105 useful for the present invention is any semiconductor material including but not limited to group IV semiconductors such as silicon, silicon germanium, or germanium, a III-V compound semiconductor, or a II-VI compound semiconductor and combination thereof. The Si wafer's surface orientation is in (111) crystalline direction. The ICs of 1110, 1120, 1130 and 1140 are any integrated circuits including but not limited to RFID tags, computer chips and computer storage chips.

Referring now to FIG. 2.2, an oxide film 1200 (preferably 10-100 nm thick) and a nitride film 1210 (preferably 50-500 nm thick) are deposited on the top surface of the ICs of 1110, 1120, 1130, and 1140. A patterned photo-resist 1220 with openings 1230 (preferably about 10-50 um in size) for trench RIE is formed. The oxide film 1200 and the nitride 1210 are deposited by any method including but not limited to CVD, PECVD, and ALD. The patterned photo-resist 1220 is formed by a conventional lithographic method. The oxide film 1200 is any oxide materials including but not limited to SiO2, Fluorine Doped Silicon Dioxide, Carbon Doped Silicon Dioxide, Porous Silicon Dioxide, Porous Carbon doped Silicon Dioxide, Spin-on organic polymeric dielectrics, Porous SiLK Spin-on silicone based polymeric dielectric, and combination thereof.

Referring now to cross-section FIG. 2.3, the pattern openings 1230 in the patterned photo-resist 220 have been etched into the nitride film 1210, the oxide film 1200, the areas among the ICs of 1110, 1120, 1130, and 1140, and the semiconductor substrate 1105 by a conventional reactive ion etching (RIE) process to form trench 1300 in the semiconductor structure 1105. The depth of the trench 1300 is about 20-600 um. Another embodiment is to form trench 1300 before the formation of ICs of 1110, 1120, 1130, and 1140.

Referring now to FIG. 2.4, spacers 1400 are formed on the sidewall of the trench 1300. The spacers 1400 are preferred to be nitride, but not limited to nitride materials. The spacers 1400 are formed by first deposit a layer of nitride film (preferably about 100 nm to 200 nm in thickness), and then RIE the layer of nitride film.

Referring now to FIG. 2.5, the extensions 1500 of the trenches 1300 are formed by selective etching Si through the bottom of trench 1300. The depth of the extension 1500 is about 10 micrometer to 50 micrometer.

Referring now to FIG. 2.6, the lateral channel 1600 is formed by lateral etch through Si selective to (111) crystalline surface of Si from the extensions 1500. The preferred etching method is to use wet etching, and etchant is KOH or TMAH. The lateral channels substantially connect the adjacent vertical trenches and the extensions of the vertical trenches. ICs of 1110, 1120, 1130, and 1140 are separated upon the forming of lateral channel 1600.

In another embodiment, before the formation of chips or ICs, the trenches shown in FIG. 2.3 are formed and refill them with poly-Si. After formation chips or ICs, re-open the trenches and follow FIGS. 2.4-2.6 to separate chips or ICs.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method for separating integrated circuit chips from a semiconductor wafer, the method comprising:
forming parallel, substantially vertical trenches in the semiconductor wafer;
forming etching-resistant spacers on the sidewalls of the said vertical trenches;
forming extensions of the said vertical trenches;
etching lateral channels from the extensions of the said vertical trenches; and
separating the integrated circuit chips from the semiconductor wafer.

2. The method of claim 1, wherein the said vertical trenches are formed by RIE or wet etching.

3. The method of claim 1, the area of said integrated circuit chips where is not forming trenches is protected by oxide, nitride and a combination thereof.

4. The method of claim 1, wherein said etching-resistant spacers on the said sidewalls of the said vertical trenches are formed by oxide, nitride and a combination thereof.

5. The method of claim 1, wherein said extensions of the said vertical trenches are formed continuously from the bottom of the said vertical trenches.

6. The method of claim 1, wherein said side walls of the said extensions of the said vertical trenches are not covered by said etching-resistant spacers.

7. The method of claim 1, wherein said lateral channels substantially connect the adjacent vertical trenches and said extensions of the said vertical trenches.

8. The method of claim 1, wherein said semiconductor wafer is made by Si, Ge or III-V semiconductor materials; and wherein the Si wafer's surface orientation is (111) crystalline direction.

9. The method of claim 1, wherein the lateral channels is etched by KOH or TMAH or a combination thereof.

10. A method for separating integrated circuit chips from a semiconductor wafer, the method comprising:
forming the parallel, substantially first vertical trenches in the semiconductor wafer from the front side of the silicon wafers;
forming the wider second vertical trenches from the backside of the semiconductor wafer; and
bending the semiconductor wafer to separate the integrated circuit chips each other.

11. The method of claim 10, wherein said first vertical trenches and said second vertical trenches are formed by RIE or wet etching.

12. The method of claim 10, wherein the area of integrated circuit chips where is not forming trench is protected by oxide, nitride and a combination thereof.

13. The method of claim 10, wherein said semiconductor wafer is made by Si, Ge, a III-V semiconductor material, and a combination thereof.

14. The method of claim 10, wherein said first vertical trenches and said second vertical trenches are aligned to each other.

15. The method of claim 10, wherein before bending said semiconductor wafer, the said semiconductor wafer is attached to a layer of rubber or a layer of any other elastic materials from the said backside of the said semiconductor wafer.

16. A method for separating integrated circuit chips from a semiconductor wafer, the method comprising:
forming parallel, substantially vertical trenches in the semiconductor wafer from the front side of the semiconductor wafer;
thinning down the semiconductor wafer from the backside of the semiconductor wafer; and
bending the semiconductor wafer to separate the integrated circuit chips.

17. The method of claim 16, wherein said vertical trenches are formed by RIE or wet etching.

18. The method of claim 16, wherein the area of integrated circuit chips where is not forming trench is protected by oxide, nitride, and a combination thereof.

19. The method of claim 16, wherein said semiconductor wafer is made by Si, Ge, a III-V semiconductor material, and a combination thereof.

20. The method of claim 16, wherein before bending said semiconductor wafer, the said semiconductor wafer is attached to a layer of rubber or a layer of any other elastic materials from the backside of the said semiconductor wafer.
